(19) United States
(12) Patent Application Publication
(10) Pub. No.: US 2002/0156690 A1
(43) Pub. Date: Oct. 24, 2002

(54) Automatic agency marketing method and the system of the same

(76) Inventors: Sheu Ren Yi, Hsinchu (TW); Jun Ching Wang, Tainan (TW)

Correspondence Address: Chun M. Ng, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/837,890

(22) Filed: Apr. 18, 2001

(51) Int. Cl. G06F 17/60; H03M 7/00

(52) U.S. Cl. 705/26; 705/10; 341/50

(57) ABSTRACT

The invention provides an automatic agency marketing system, which the system comprises a database and a processor. The database is used to save at least one item of product information. The processor coupled with the database, wherein the processor is used to execute following items comprising: (1) receiving a 1^{st} product order message transmitted from a 1^{st} consumer by internet, (2) generating a 1^{st} agency identification information of the 1^{st} consumer's product sales qualification according to the 1^{st} product order message, (3) encoding the 1^{st} agency identification information and a product taken out from the database to a 1^{st} electric file and transmitting the 1^{st} electric file to the 1^{st} consumer, wherein the 1^{st} electric file can be decoded by the 1^{st} consumer to take out the product.

### FIELD OF THE INVENTION

The present invention relates to an agency marketing method and the system of the same, more specifically, the present invention relates to an automatic agency marketing method and the system of the same.

### DESCRIPTION OF THE PRIOR ART

In the merchandised society, the two major business running models that products (or merchandise) are sold from producer to the customers are: directly sales model and indirectly sales model. In the indirectly sales model, one of the examples is through agency to transfer products to customers. It usually goes by agency acquire products selling privilege from the producers, then the agency sells products to the customers by marketing channels (such as actual or virtual distribution etc.). However, when the agency wants to become the products selling agency from the producers, it is done by times communication in phones, mails or faxes (including internet e-mails or faxes) between the agency and the producers. Even after meetings, the contract for product selling agency is settled and agency actually acquires the selling privilege by the contract.

In the above mentioned business running model that agency transfers the products to the customers, it takes a very long time for agency to acquire the products selling privilege, and that causes a extension of the time that products sold from producer to customers. Also, traditional product marketing usually takes a considerable cost to build up the marketing channels that causes an increase on the final cost of products. Besides, with a rapid improvement of electronic medias, the distance of information transferring between producers and customers is gradually decreasing. The old economic marketing model such as above-mentioned business running model of agency rules has become too far away from the developing speed of nowadays technology. It has resulted that many products invented for convenient life are unable of promotion in the market due to lack of marketing cost and marketing channels.

Based on this reason, it has become our pursuing objective to minimize the time for product marketing by using more suitable new economic marketing model for modern electronic medias technology and making product invention and marketing on the same level.

### SUMMARY OF THE INVENTION

The main objective of this invention is to provide an automatic agency marketing method and the system of the same in order to simplify the product agency system.

The other objective of this invention is to provide an automatic agency marketing method and the system of the same by simplified product agency system to expand products marketing channels rapidly.

According to one embodiment of this invention, automatic agency marketing system comprises a database and a processor. The database is used to save at least one item of product information. The processor coupled with the database, wherein the processor is used to execute following items comprising:

(1) receiving a 1^{st} registration information of member application transmitted from a 1^{st} consumer by internet;

(2)assigning and transmitting a 1^{st} member identification information representing a membership qualification to the 1^{st} consumer according to the 1^{st} registration information, and building up a 1^{st} consumer's membership information in the database, the 1^{st} consumer who has the 1^{st} member identification information is called a 1^{st} member;

(3) receiving a 1^{st} product order message transmitted from the 1^{st} member by internet, wherein the product can be transmitted by internet;

(4) generating a 1^{st} agency identification information of the 1^{st} member's product sales qualification according to the 1^{st} product order message;

(5) encoding the 1^{st} agency identification information and the product taken out from the database to a 1^{st} electric file and transmitting the 1^{st} electric file to the 1^{st} member, the 1^{st} electric file can be decoded by the 1^{st} member to take out the product;

(6) receiving a 2^{nd} registration information of member application transmitted from a 2^{nd} consumer by internet;

(7)assigning and transmitting a 2^{nd} member identification information representing a membership qualification to the 2^{nd} consumer according to the 2^{nd} registration information, and building up a 2^{nd} consumer's membership information in the database, the 2^{nd} consumer who has the 2^{nd} member identification information is called a 2^{nd} member;

(8) receiving the 1^{st} electric file and a 2^{nd} product order message transmitted from the 2^{nd} member by internet, wherein the 1^{st} electric file transmitted from the 2^{nd} member is acquired from the 1^{st} member;

(9) generating a 2^{nd} agency identification information of the 2^{nd} member's product sales qualification according to the 2^{nd} product order message;

(10) decoding the 1^{st} electric file in order to take out the 1^{st} agency identification information;

(11) encoding the 2^{nd} agency identification information and the product to a 2^{nd} electric file and transmitting the 2^{nd} electric file to the 2^{nd} consumer, the 2^{nd} electric file can be decoded by the 2^{nd} consumer to take out the product; and

(12) assigning a sales profits to the 1^{st} consumer who has the 1^{st} agency identification information.

According to one embodiment of this invention, automatic agency marketing method comprises the steps of:

(1) A 1^{st} consumer transmits a 1^{st} registration information of member application to a server of product supplier by internet;

(2) According to the 1^{st} registration information, the server assigns and transmits a 1^{st} member identification information representing a membership qualification to the 1^{st} consumer; and builds up a 1^{st} consumer's membership information in the server. The 1^{st} consumer who has the 1^{st} member identification information is called a 1^{st} member;

(3) The 1^{st} member transmits a product order message to the server by internet, wherein the product can be transmitted by internet;

(4) According to the order message, the server encodes a 1^{st} agency identification information of the 1^{st} member's product sales qualification and the product wanted by the 1^{st} member to a 1^{st} electric file; then transmits the 1^{st} electric file to the 1^{st} member and builds up an information representing the 1^{st} member's sales qualification in the server. The 1^{st} electric file can be decoded by the 1^{st} member to take out the product;

(5) A 2^{nd} consumer transmits a 2^{nd} registration information of member application to the server of product supplier by internet;

(6) According to the 2^{nd} registration information, the server assigns and transmits a 2^{nd} member identification information representing a membership qualification to the 2^{nd} consumer; and builds up a 2^{nd} consumer's membership information in the server. The 2^{nd} consumer who has the 2^{nd} member identification information is called a 2^{nd} member;

(7) By internet, the 2^{nd} member transmits the 1^{st} electric file obtained from the 1^{st} member and the purchasing order information to the server for buying the product; and

(8) The server encodes a 2^{nd} agency identification information of the 2^{nd} member's product sales qualification and the product wanted by the 2^{nd} member to a 2^{nd} electric file; then transmits the 2^{nd} electric file to the 2^{nd} member, builds up an 10 information representing the 2^{nd} member's sales qualification in the server, identifies the 1^{st} agency identification information from the 1^{st} electric file and assigns a sales profits to the 1^{st} member who has the 1^{st} agency identification information.

The product needed for encoding the 2^{nd} electric file can be taken out from the database or the 1^{st} electric file. The database comprising the member database and the product database. The member database is used to save the member information including member identification information and sales identification information. The product database is used to save at least one item of product information.

### BRIEF DESCRIPTION OF THE DRAWINGS

FIG. 1 is the flow chart for automatic agency marketing method according to the 1^{st} embodiment of this invention;

FIG. 2 is the flow chart for automatic agency marketing method according to the 2^{nd} embodiment of this invention;

FIG. 3 is the flow chart for automatic agency marketing method according to the 3^{rd} embodiment of this invention; and

FIG. 4 is the block diagram for automatic agency marketing system according to the 1^{st} embodiment of this invention.

### DESCRIPTION OF THE PREFERRED EMBODIMENT

The main objective of this invention is to provide an automatic agency marketing method and the system of the same in order to simplify the product agency system.

The other objective of this invention is to provide an automatic agency marketing method and the system of the same by simplified product agency system to expand products marketing channels rapidly.

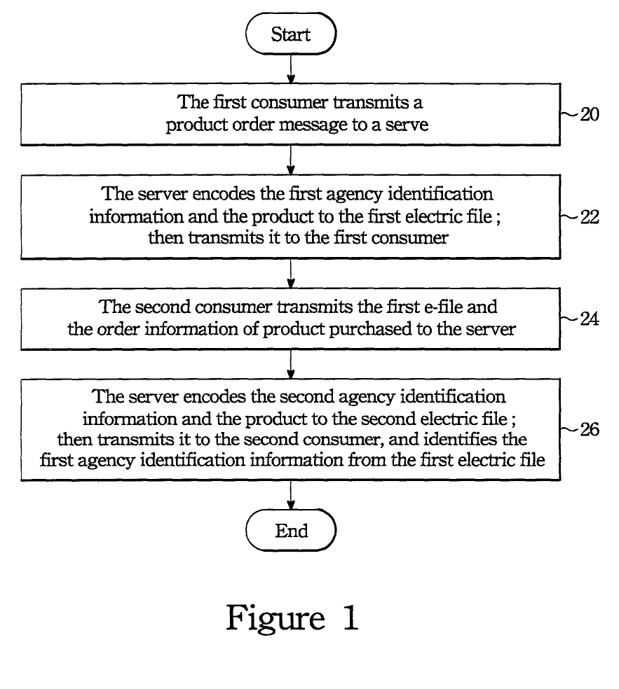

According to the 1^{st} embodiment of this invention, automatic agency marketing method (please refer to FIG. 1) comprises:

(1)A 1^{st} consumer transmits a product order message to a server of the system by internet, wherein the product can be transmitted by internet (Step 20);

(2) According to the order message, the server encodes a 1^{st} agency identification information of the 1^{st} consumer's product sales qualification and the product wanted by the 1^{st} consumer to a 1^{st} electric file; then transmits the 1^{st} electric file to the 1^{st} consumer and builds up an information representing the 1^{st} consumer's sales qualification in the server. The 1^{st} electric file can be decoded by the 1^{st} consumer to take out the product (Step 22);

(3) By internet, a 2^{nd} consumer transmits the 1^{st} electric file obtained from the 1^{st} consumer and the order information of product to the server for buying the product (Step 24); and

(4) The server encodes a 2^{nd} agency identification information of the 2^{nd} consumer's product sales qualification and the product wanted by the 2^{nd} consumer to a 2^{nd} electric file; then transmits the 2^{nd} electric file to the 2^{nd} consumer, builds up an information representing the 2^{nd} consumer's sales qualification in the server, and identifies the 1^{st} agency identification information from the 1^{st} electric file. The 2^{nd} electric file can be decoded by the 2^{nd} consumer to take out the product (Step 26).

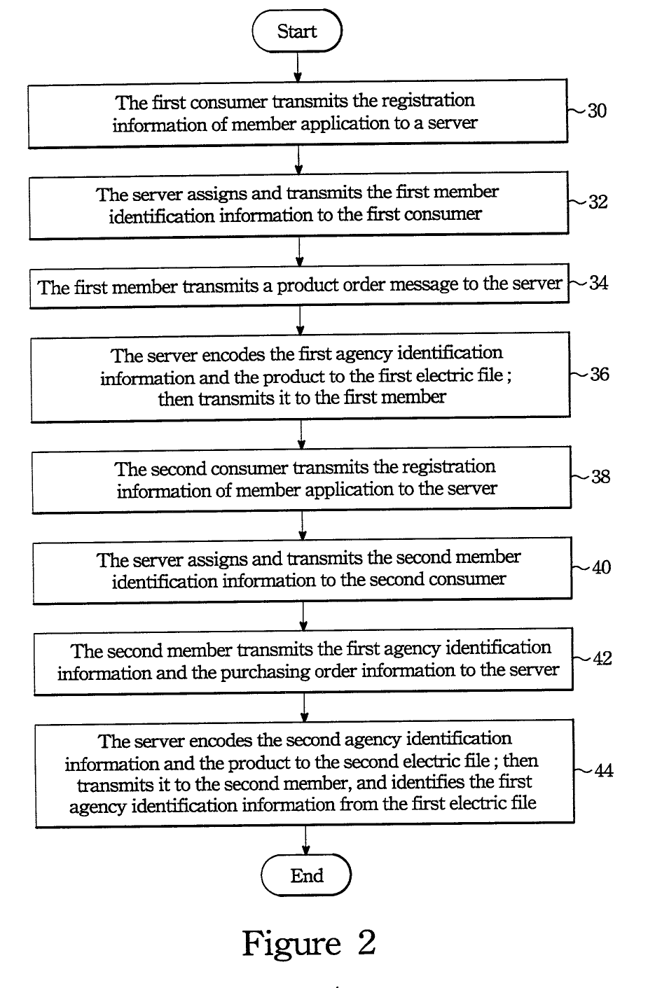

According to the 2^{nd} embodiment of this invention, automatic agency marketing method (please refer to FIG. 2) comprises:

(1) A 1^{st} consumer transmits a 1^{st} registration information of member application to a server of product supplier by internet (Step 30);

(2) According to the 1^{st} registration information, the server assigns and transmits a 1^{st} member identification information representing a membership qualification to the 1^{st} consumer; and builds up a 1^{st} consumer's membership information in the server. The 1^{st} consumer who has the 1^{st} member identification information is called a 1^{st} member (Step 32);

(3) The 1^{st} member transmits a product order message to the server by internet, wherein the product can be transmitted by internet (Step 34);

(4) According to the order message, the server encodes a 1^{st} agency identification information of the 1^{st} member's product sales qualification and the product wanted by the 1^{st} member to a 1^{st} electric file; then transmits the 1^{st} electric file to the 1^{st} member and builds up an information representing the 1^{st} member's sales qualification in the server. The 1^{st} electric file can be decoded by the 1^{st} member to take out the product (Step 36);

(5) A 2^{nd} consumer transmits a 2^{nd} registration information of member application to the server of product supplier by internet (Step 38);

(6) According to the 2^{nd} registration information, the server assigns and transmits a 2^{nd} member identification information representing a membership qualification to the 2^{nd} consumer; and

builds up a 2^{nd} consumer's membership information in the server. The 2^{nd} consumer who has the 2^{nd} member identification information is called a 2^{nd} member (Step 40);

(7) By internet, the 2^{nd} member transmits the 1^{st} agency identification information obtained from the 1^{st} member and the purchasing order information of the 1^{st} member sales' product to the server for buying the product (Step 42); and

(8) The server encodes a 2^{nd} agency identification information of the 2^{nd} member's product sales qualification and the product wanted by the 2^{nd} member to a 2^{nd} electric file; then transmits the 2^{nd} electric file to the 2^{nd} member, builds up an information representing the 2^{nd} member's sales qualification in the server, and identifies the 1^{st} agency identification information from the 1^{st} electric file. The 2^{nd} electric file can be decoded by the 2^{nd} member to take out the product (Step 44).

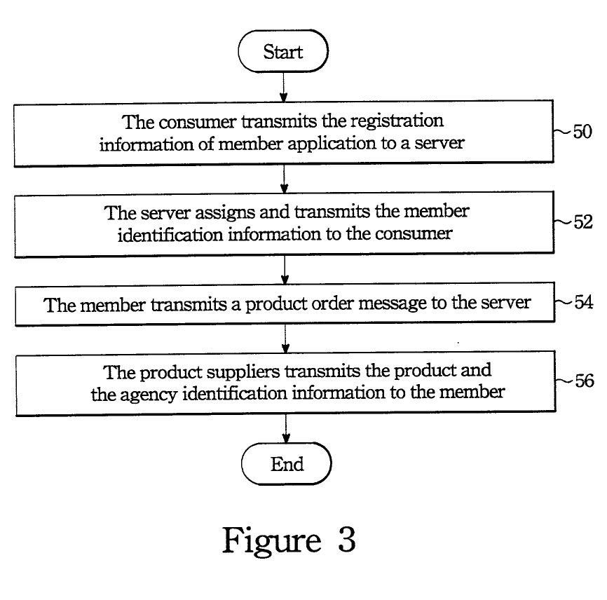

According to the 3^{rd} embodiment of this invention, automatic agency marketing method (please refer to FIG. 3) comprises:

(1) A consumer transmits the registration information of member application to a server of product supplier by internet (Step 50);

(2) According to the registration information, the server assigns and transmits a member identification information representing a membership qualification to the consumer; and builds up a consumer's membership information in the server. The consumer who has the member identification information is called a member (Step 52);

(3) The member transmits a product order message to the server by internet (Step 54); and

(4) According to the order information, the product supplier transmits the product which the member wants to buy and also an agency identification information representing product sales qualification to the member; and builds up an information representing the member's sales qualification in the server (Step 56).

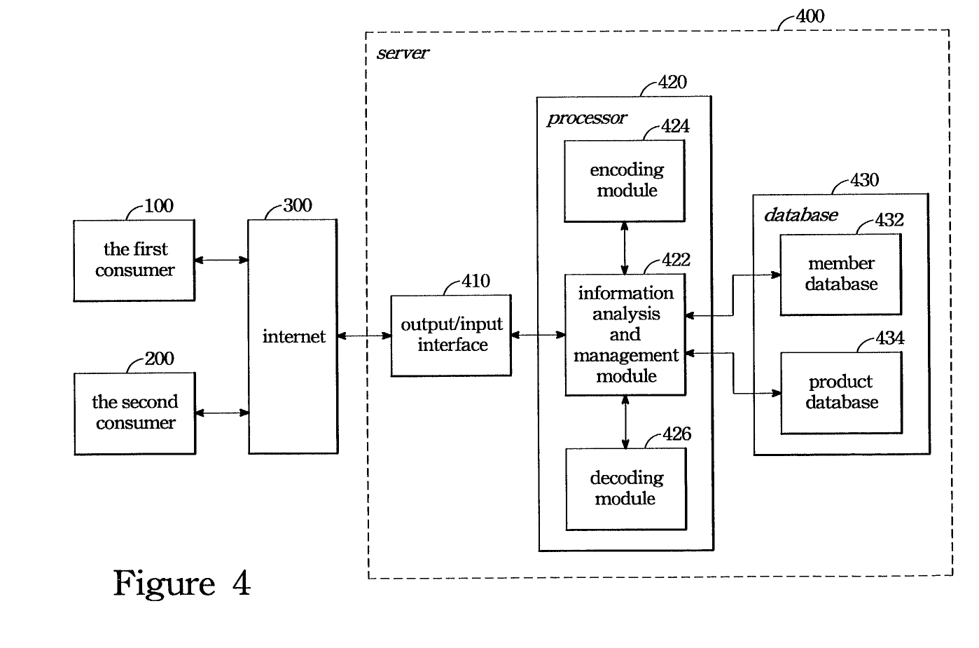

According to the first embodiment of this invention, the server system 400 (please refer to the FIG. 4) within automatic agency marketing method comprises: an output/input interface 410, a processor 420 coupled with the output/input interface 410, and a database 430 coupled with processor 420. The output/input interface 410 is the mutual communication interface between the server system 400 and the outsiders. The database 430 comprises the member database 432 and the product database 434. The member database 432 is used to save the member information including member identification information and sales identification information etc. And the product database 434 is used to save at least one item of product information. As to the processor 420 comprises: encoding module 424, decoding module 426 and information analysis and management module 422.

The encoding module 424 is used to create member identification information of member qualification, agency identification information of product sales qualification, and to encode a agency identification information and the product to a electric file. The decoding module 426 is used to decode the electric file to separate the agency identification information and the product. Also, an information analysis and management module 422 coupled with the database 430, the encoding module 424 and the decoding module 426, where an information analysis and management module 422 is used to execute following items comprising:

(1)transmitting information mutually through the output/input interface 410 with the consumers (such as the 1^{st} consumer 100 or the 2^{nd} consumer 200) by internet 300;

(2)ordering the encoding module 424 and the decoding module 426 to process encoding and decoding, and report the results of encoding and decoding;

(3)saving or deleting an information of the database 430.

In the above embodiment of the invention, the products needed for the 2^{nd} electric file encoding can be retrieved from the database 430 or the 1^{st} electric file. The 1^{st} electric file transmitted to the 1^{st} member (or the 1^{st} consumer 100) can be decoded by the 1^{st} member (or the 1^{st} consumer 100) to take out this product; the 2^{nd} electric file transmitted to the 2^{nd} member (or 2^{nd} consumer 200) can be decoded by the 2^{nd} member (or 2^{nd} consumer 200) to take out this product. After the server system 400 (or the processor 420) identifying the 1^{st} agency identification information from the 1^{st} electric file, it also comprises the step to assign a sales profits to the 1^{st} member (or the 1^{st} consumer 100) who has the 1^{st} agency identification information.

As known from above, the automatic agent marketing methods and the system of the same of this invention can simplify the product agent sales system and expand the product marketing channels rapidly.

As is understood by a person skilled in the art, the foregoing embodiments of the present invention are illustrated of the present invention rather than limiting of the present invention. It is intended to cover various modifications and similar arrangements included within the spirit and scope of the appended claims, the scope of which should be accorded the broadest interpretation in order to encompass all such modifications and similar structure.

What is claimed is:

1. An automatic agency marketing method, said method comprising the steps of:
transmitting a product order message of a 1^{st} consumer from said 1^{st} consumer to a server by internet, wherein said product can be transmitted by internet;
encoding a 1^{st} agency identification information of said 1^{st} consumer's product sales qualification and said product wanted by said 1^{st} consumer to a 1^{st} electric file by said server according to said order message, transmitting said 1^{st} electric file to said 1^{st} consumer and building up an information representing said 1^{st} consumer's sales qualification in said server;
transmitting said 1^{st} electric file obtained from said 1^{st} consumer and said order information of product of a 2^{nd} consumer to said server by internet for buying said product; and
encoding a 2^{nd} agency identification information of said 2^{nd} consumer's product sales qualification and said product wanted by said 2^{nd} consumer to a 2^{nd} electric file by said server, transmitting said 2^{nd} electric file to said 2^{nd} consumer, building up an information representing said 2^{nd} consumer's sales qualification in said server, and identifying said 1^{st} agency identification information from said 1^{st} electric file.

2. The method according to claim 1, wherein said product needed for encoding said 2^{nd} electric file can be taken out from said server or said 1^{st} electric file.

3. The method according to claim 1, wherein said 1^{st} electric file can be decoded by said 1^{st} consumer to take out said product.

4. The method according to claim 1, wherein said 2^{nd} electric file can be decoded by said 2^{nd} consumer to take out said product.

5. The method according to claim 1, further comprising the step of assigning the sales profits to said 1^{st} consumer who has said 1^{st} agency identification information after identifying said 1^{st} agency identification information from said 1^{st} electric file.

6. An automatic agency marketing method, said method comprising the steps of:
transmitting a registration information of member application from a consumer to a server of product supplier by internet;
assigning and transmitting a member identification information representing a membership qualification to said consumer by said server according to said registration information, and building up said consumer's membership information in said server, wherein said consumer who has said member identification information is called a 1^{st} member;
transmitting a product order message of said member from said member to said server by internet; and
transmitting said product which said member wants to buy and also said agency identification information representing product sales qualification to said member by said product supplier according to said order information, and building up an information representing said member's sales qualification in said server.

7. An automatic agency marketing system, said system comprising:
a database used to save at least one item of product information.;
a processor coupled with said database, wherein said processor is used to execute following items comprising:
receiving a 1^{st} registration information of member application transmitted from the 1^{st} consumer by internet;
assigning and transmitting a 1^{st} member identification information representing a membership qualification to said 1^{st} consumer according to said 1^{st} registration information, and building up a 1^{st} consumer's membership information in said database, said 1^{st} consumer who has said 1^{st} member identification information is called a 1^{st} member;
receiving a 1^{st} product order message transmitted from said 1^{st} member by internet, wherein said product can be transmitted by internet;
generating a 1^{st} agency identification information of said 1^{st} member's product sales qualification according to said 1^{st} product order message;
encoding said 1^{st} agency identification information and said product taken out from said database to a 1^{st} electric file and transmitting said 1^{st} electric file to said 1^{st} member, said 1^{st} electric file can be decoded by said 1^{st} member to take out said product;
receiving a 2^{nd} registration information of member application transmitted from the 2^{nd} consumer by internet;
assigning and transmitting a 2^{nd} member identification information representing a membership qualification to said 2^{nd} consumer according to said 2^{nd} registration information, and building up a 2^{nd} consumer's membership information in said database, said 2^{nd} consumer who has said 2^{nd} member identification information is called a 2^{nd} member;
receiving said 1^{st} electric file and a 2^{nd} product order message transmitted from said 2^{nd} member by internet, wherein said 1^{st} electric file transmitted from said 2^{nd} member is acquired from said 1^{st} member;
generating a 2^{nd} agency identification information of said 2^{nd} member's product sales qualification according to said 2^{nd} product order message;
decoding said 1^{st} electric file in order to take out said 1^{st} agency identification information; and
encoding said 2^{nd} agency identification information and said product to the 2^{nd} electric file and transmitting said 2^{nd} electric file to said 2^{nd} consumer, said 2^{nd} electric file can be decoded by said 2^{nd} consumer to take out said product.

8. The system according to claim 7, wherein said 1^{st} electric file can be decoded by said 1^{st} member to take out said product.

9. The system according to claim 7, wherein said 2^{nd} electric file can be decoded by said 2^{nd} member to take out said product.

10. The system according to claim 7, wherein said product needed for encoding said 2^{nd} electric file can be taken out from said database or said 1^{st} electric file.

11. The system according to claim 7, wherein said database comprising:
a member database used to save the member information including member identification information and sales identification information; and
a product database used to save at least one item of said product information.

12. The system according to claim 7, wherein said processor comprising:
an encoding module used to create member identification information of member qualification, agency identification information of product sales qualification, and to encode said agency identification information and said product to a electric file;
a decoding module used to decode said electric file to separate said agency identification information and said product.; and
an information analysis and management module coupled with said database, said encoding module and said decoding module, wherein said information analysis and management module is used to execute following items comprising:
transmitting information mutually with said consumer by internet;
ordering said encoding module and said decoding module to process encoding and decoding, and reporting the results of said encoding and said decoding; and
saving or deleting an information of said database.

13. The system according to claim 7, wherein said processor further comprising execute the step of assigning a sales profits to said 1^{st} consumer who has said 1^{st} agency identification information after decoding said 1^{st} electric file in order to take out said 1^{st} agency identification information.

14. An automatic agency marketing system, said system comprising:
a database used to save at least one item of product information.;
a processor coupled with said database, used to execute following items comprising:
receiving a 1^{st} product order message transmitted from a 1^{st} consumer by internet;
generating a 1^{st} agency identification information of said 1^{st} consumer's product sales qualification according to said 1^{st} product order message;
encoding said 1^{st} agency identification information and said product taken out from said database to a 1^{st} electric file and transmitting said 1^{st} electric file to said 1^{st} consumer.

15. The system according to claim 14, wherein said 1^{st} electric file can be decoded by said 1^{st} consumer to take out said product.

16. The system according to claim 14, wherein said processor comprising:
an encoding module used to create agency identification information of product sales qualification and to encode said agency identification information and said product to a electric file;
a decoding module used to decode said electric file to separate said agency identification information and said product.; and
an information analysis and management module coupled with said database, said encoding module and said decoding module, wherein said information analysis and management module is used to execute following items comprising:
transmitting information mutually with said consumer by internet;
ordering said encoding module and said decoding module to process encoding and decoding, and reporting the results of said encoding and said decoding; and
saving or deleting an information of said database.

17. The system according to claim 14, wherein said processor further comprising execute following items:
receiving said 1^{st} electric file and a 2^{nd} product order message transmitted from said 2^{nd} member by internet, wherein said 1^{st} electric file transmitted from said 2^{nd} member is acquired from said 1^{st} member;
generating a 2^{nd} agency identification information of said 2^{nd} member's product sales qualification according to said 2^{nd} product order message;
decoding said 1^{st} electric file in order to take out said 1^{st} agency identification information; and
encoding said 2^{nd} agency identification information and said product to a 2^{nd} electric file and transmitting said 2^{nd} electric file to said 2^{nd} consumer.

18. The system according to claim 17, wherein said 2^{nd} electric file can be decoded by said 2^{nd} consumer to take out said product.

19. The system according to claim 17, wherein said processor further comprising execute the step of assigning a sales profits to said 1^{st} consumer who has said 1^{st} agency identification information after decoding said 1^{st} electric file in order to take out said 1^{st} agency identification information.
